(19) United States
(12) Patent Application Publication
(10) Pub. No.: US 2012/0127444 A1
(43) Pub. Date: May 24, 2012

(54) Reflection Mask For EUV Lithography, System For EUV Lithography, And Method Of Fixing The Reflection Mask For EUV Lithography

(75) Inventors: Sung-min Huh, Yongin-si (KR); Dong-gun Lee, Hwaseong-si (KR); In-yong Kang, Seoul (KR)

(73) Assignee: SAMSUNG ELECTRONICS CO., LTD., Suwon-si (KR)

(21) Appl. No.: 13/221,286

(22) Filed: Aug. 30, 2011

(30) Foreign Application Priority Data
Nov. 22, 2010 (KR) 10-2010-0116217

(51) Int. Cl. G03B 27/70; G03F 1/00

(52) U.S. Cl. 355/66; 430/5

(57) ABSTRACT

Example embodiments of the inventive concepts relate to a reflection mask including an upper surface configured to reflect extreme ultraviolet EUV light, a lower surface opposite the upper surface, where the lower surface includes at least one alignment key. The reflection mask may include a conductive layer, a substrate on the conductive layer, a reflection layer on the substrate, and an absorption pattern on the reflection layer. The reflection layer may define the upper surface configured to reflect extreme ultraviolet EUV light. The absorption pattern may expose the upper surface of the reflection layer.

### CROSS-REFERENCE TO RELATED APPLICATIONS

This application claims priority under 35 U.S.C. §119 to the benefit of Korean Patent Application No. 10-2010-0116217, filed on Nov. 22, 2010, in the Korean Intellectual Property Office, the disclosure of which is incorporated herein in its entirety by reference.

### BACKGROUND

1. Field

Example embodiments of inventive concepts relate to a reflection mask for lithography, a system for lithography, and/or a method of fixing the reflection mask for lithography. More particularly, example embodiments of inventive concepts relate to a reflection mask that may be used in extreme ultraviolet (EUV) photolithography using EUV light having a central wavelength of 13.5 nm, a system that may be used for EUV lithography, and a method of fixing the reflection mask that may be used for EUV lithography.

2. Relevant Art

As semiconductor devices are more highly integrated, a light source for lithography used in photolithography may have a shorter wavelength. An example of a lithography method for embodying a pattern size of 100 nm or less is a technique using a wavelength range of a EUV light. A lithography method using EUV light uses a reflection mask instead of a conventional transmissive mask, which results in various unexpected problems.

### SUMMARY

Example embodiments of inventive concepts relate to a reflection mask for lithography, a system for lithography, and/or a method of fixing the reflection mask for lithography.

Example embodiments of the inventive concepts relate to a reflection mask including an upper surface configured to reflect extreme ultraviolet EUV light, a lower surface opposite the upper surface, where the lower surface includes at least one alignment key.

The reflection mask may include a conductive layer, a substrate on the conductive layer, a reflection layer on the substrate, and an absorption pattern on the reflection layer. The reflection layer may define the upper surface configured to reflect extreme ultraviolet EUV light. The absorption pattern may expose the upper surface of the reflection layer. An edge of the substrate may extend a distance wider than an edge of the conductive layer. An area size of the conductive layer may be smaller than an area size of the substrate. The conductive layer may include the at least one alignment key. The conductive layer may expose a portion of the substrate and the exposed portion of the substrate may include the at least one alignment key.

The conductive layer may include a lowermost surface of the reflection mask. The conductive layer may be configured to attach to an electrostatic chuck (ESC) in order to fix the reflection mask to the ESC. The ESC may include a sensor that is configured to sense the at least one alignment key in order for at least one drive unit to align the reflection mask and the ESC.

The at least one alignment key may be protrude from the reflection mask.

The alignment key may have a concave pattern that is defined by the lower surface of the reflection mask.

The alignment key may include at least one of a line-shape, a polygonal shape, an oval shape, and a circular shape.

A first region of the lower surface of the reflection mask includes at least one of the at least one alignment key, and a second region of the lower surface of the reflection mask includes at least one of the at least one alignment key.

The reflection mask may further include an absorption pattern that exposes the upper surface configured to reflect extreme ultraviolet EUV light.

The reflection mask may further include a protection layer between the upper surface and the lower surface.

A conductive layer of the reflection mask may include the lowermost surface of the reflection mask. The lowermost surface of the reflection mask may include the lower surface including the at least one alignment key. The lowermost surface of the reflection mask may include a first region and a second region. The first region of the conductive layer may include a plurality of first alignment keys. The second region of the conductive layer may surround the first region of the conductive layer. The second region of the conductive layer may include a plurality of second alignment keys. A size of the first alignment keys in the first region may be smaller than a size of the at second alignment keys in the second region. A substrate may be on the conductive layer. The conductive layer may expose a portion of the substrate. The exposed portion of the substrate may include a plurality of third alignment keys.

According to example embodiments of the inventive concepts, a system may include a reflection mask including an upper surface configured to reflect extreme ultraviolet EUV light, a lower surface opposite the upper surface, where the lower surface includes at least one alignment key. The system may further include an array of a plurality of pins configured to contact a lowermost surface of the reflection mask, and an electrostatic chuck (ESC) including an alignment sensor. The alignment sensor may be configured to sense the alignment key of the reflection mask.

At least one drive unit may be configured to move one of the reflection mask and the ESC relative to each other, based on a reference to the least one alignment key.

The reflection mask may include a conductive layer, a substrate on the conductive layer, a reflection layer on the substrate, and an absorption pattern on the reflection layer. The reflection layer may define the upper surface configured to reflect extreme ultraviolet EUV light. The absorption pattern may expose the upper surface of the reflection layer.

The conductive layer may include a first region and a second region: a first region contacting the array of pins and a second region surrounding the first region, wherein a size of the alignment key in the first region may be smaller than a size of the alignment key in the second region.

According to example embodiments of the inventive concepts, a reflection mask may include a reflection layer including an upper surface. The reflection layer may include a plurality of alternating silicon films and non-silicon films, the non-silicon films including one of molybdenum (Mo) and beryllium (Be). The reflection mask may include a lower surface including at least one alignment key.

According to example embodiments of the inventive concepts, a system may include an electrostatic chuck (ESC) that includes an alignment sensor and a plurality of pins. The alignment sensor may be configured to sense at least one alignment key on a lower surface of a reflection mask. The plurality of pins configured to contact a lowermost surface of the reflection mask, and the reflection mask may include an upper surface configured to reflect extreme ultraviolet EUV light.

According to an example embodiments of the inventive concepts, a method of fixing a reflection mask for extreme ultraviolet (EUV) lithography on an electrostatic chuck (ESC) may include: preparing a reflection mask for EUV lithography, the reflection mask including an uppermost surface by which EUV light is reflected; a lowermost surface facing the uppermost surface; and an alignment key disposed on the lowermost surface of the reflection mask; preparing an ESC comprising a array of a plurality of pins that contact the lowermost surface of the reflection mask and an alignment sensor for sensing the alignment key; identifying defects on the lowermost surface of the reflection mask with reference to the alignment key; relatively moving the reflection mask and the ESC so as not to overlap positions of defects with positions of the array of pins; and attaching the reflection mask to the array of pins.

The identifying of the defects on the lowermost surface of the reflection mask with reference to the alignment key may include determining of position, size, height, or shape of the defects.

The identifying of the defects on the lowermost surface of the reflection mask with reference to the alignment key may include classifying the defects according to type.

The classifying of the detects comprises classifying defects into a first defect that may be removed by washing, a second defect that is removed by laser-repairing, and a third defect that is not removed by washing and/or laser-repairing.

The identifying of the defects on the lowermost surface of the reflection mask with reference to the alignment key, the method may further include washing the lowermost surface of the reflection mask to remove the first defect.

The identifying of the defects on the lowermost surface of the reflection mask with reference to the alignment key, the method may further include laser-repairing the lowermost surface of the reflection mask to remove the second defect.

In the relatively moving the reflection mask and the ESC so as not to overlap positions of defects with positions of the array of pins, the defects may include the third defect.

### BRIEF DESCRIPTION OF THE DRAWINGS

The foregoing and other features and advantages of inventive concepts will be apparent from the more particular description of non-limiting embodiments of inventive concepts, as illustrated in the accompanying drawings in which like reference characters refer to the same parts throughout the different views. The drawings are not necessarily to scale, emphasis instead being placed upon illustrating the principles of inventive concepts. In the drawings:

FIG. 1 is a schematic view of a system that is used for EUV lithography and includes a reflection mask for EUV lithography, according to example embodiments of the inventive concepts;

FIGS. 2 through 5 are plan views each illustrating a position where an alignment key is disposed according to example embodiments of the inventive concepts;

FIGS. 6 and 7 are plan views each illustrating the number of alignment keys according to example embodiments of the inventive concepts;

FIGS. 8A through 8L are plan views of alignment keys according to example embodiments of the inventive concepts;

FIG. 9 is a perspective view of alignment key according to example embodiments of the inventive concepts, in which the alignment key has a concave pattern;

FIG. 10 is a perspective view of an alignment key according to another example embodiments of the inventive concepts, in which the alignment key has a convex pattern;

FIG. 11 is a flowchart for explaining a method of fixing a reflection mask for EUV lithography on an electrostatic chuck (ESC), according to example embodiments of the inventive concepts;

FIGS. 12A and 12B are, respectively, plan and sectional views illustrating operation in which defects on a lowermost surface of a reflection mask for EUV lithography are identified with reference to an alignment key; and

FIGS. 13A and 13B are, respectively, plan and sectional cross-sectional views illustrating operation in which a reflection mask for EUV lithography and an ESC are relatively moved with reference to an alignment key and operation in which the reflection mask is attached to an array of a plurality of pins, according to example embodiments of the inventive concepts.

### DETAILED DESCRIPTION OF THE EMBODIMENTS

Hereinafter, the example embodiments will be described in detail with reference to the attached drawings. The embodiments may, however, have many different fowls and should not be construed as being limited to those set forth herein; rather, these embodiments are provided so that this disclosure will be thorough and complete, and will fully convey the concepts of example embodiments to those of ordinary skill in the art. In the drawings, the sizes of elements are exaggerated for clarity. Like reference numerals in the drawings denote like elements, and thus their description will be omitted.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. As used herein the teem “and/or” includes any and all combinations of one or more of the associated listed items. Other words used to describe the relationship between elements or layers should be interpreted in a like fashion (e.g., “between” versus “directly between,” “adjacent” versus “directly adjacent,” “on” versus “directly on”). It will be understood that when an element, such as a layer, a region, or a substrate, is referred to as being “on” another element, it may be directly on the other element or intervening elements may be present. In contrast, when an element is referred to as being “directly on,” another element, there are no intervening elements present. Like reference numerals refer to like elements throughout.

The terms “first,” “second,” and the like are used to describe various members, elements, regions, layers and/or parts, but these members, elements, regions, layers and/or parts are not limited by these terms. These twits are used only to distinguish one member, element, region, layer, or part from another member, element, region, layer, or part. Accordingly, a first member, element, region, layer, or part may denote a second member, element, region, layer, or part without deviating from the scope of the inventive concept.

Also, relative terms such as “uppermost” or “upper” and “lowermost” or “lower” may be used herein to describe a relationship between elements as illustrated in drawings. The relative terms may include other directions in additional to a direction shown in the drawings. For example, when a device is turned over in the drawings, elements that are described to exist on upper surfaces of other elements now exist on lower surfaces of the other elements. Accordingly, the term “upper” used as the example may include “lower” and “upper” directions with reference to a certain direction of the drawings. If a device faces another direction (90° rotation), the relative terms may be interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the teens “comprises”, “comprising”, “includes” and/or “including,” if used herein, specify the presence of stated features, integers, steps, operations, elements and/or components, but do not preclude the presence or addition of one or more other features, integers, steps, operations, elements, components and/or groups thereof.

Example embodiments are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms used herein have the same meaning as commonly understood by one of ordinary skill in the art to which example embodiments belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

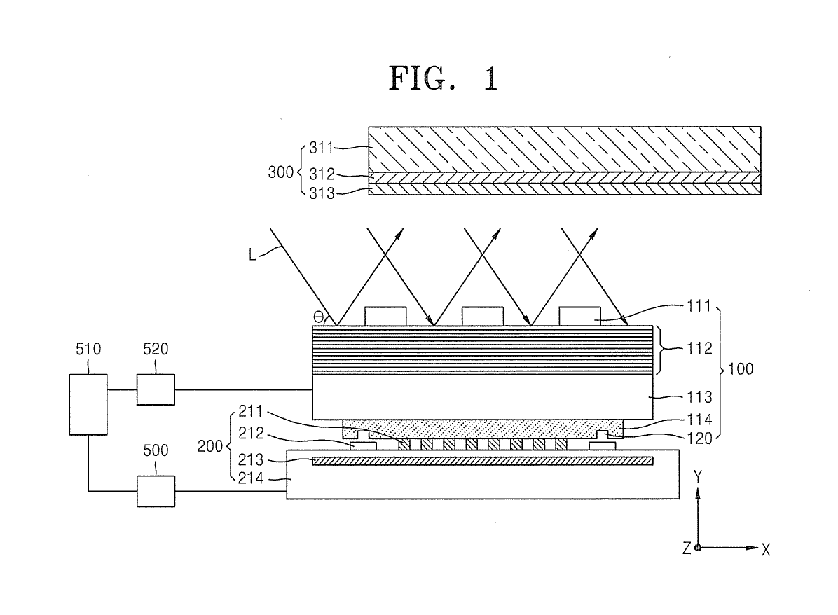

FIG. 1 is a schematic view of a system that is used for EUV lithography and includes a reflection mask 100 for EUV lithography, according to example embodiments of the inventive concepts. While FIG. 1 illustrates a reflection mask 100 for EUV lithography, example embodiments are not limited thereto and may include reflection masks used for lithography processes other than EUV lithography.

In FIG. 1, an X-axis is a right direction, a Y-axis is an upward direction, and a Z-axis is a coming-out direction from the paper. All axes used in the following drawings may be understood by referring to the three axes.

The reflection mask 100 may include a conductive layer 114, a substrate 113 disposed on the conductive layer 114, a reflection layer 112 disposed on the substrate 113, and an absorption pattern 111 disposed on the reflection layer 112.

The reflection layer 112 may be disposed on an upper surface of the substrate 113. The substrate 113 may include at least one of quartz, glass, and silicon, but example embodiments are not limited thereto. The reflection layer 112 may have a stack structure formed by alternately depositing a molybdenum (Mo) film and a silicon (Si) film a plurality of times (for example, 40 to 50 times), but example embodiments are not limited thereto. An uppermost layer of the reflection layer 112 may be a Mo film or a Si film. For example, the uppermost layer of the reflection layer 112 may be a Si film because a natural oxidation film disposed on the surface of silicon has excellent stability. Each of the Mo film and Si film may have a thickness of a few nm. Alternatively, the reflection layer 112 may also have a stack structure of a beryllium (Be) film and a Si film, instead of a Mo film and a Si film.

The absorption pattern 111 may be disposed on an upper surface of the reflection layer 112. The absorption pattern 111 may include a tantalum nitride (TaN) film, which absorbs extreme ultraviolet (EUV) light L, and may be formed in a desired (or alternatively predetermined pattern), thereby forming an EUV light L absorption region.

Although not illustrated herein, a protection layer may be interposed between the reflection layer 112 and the absorption pattern 111, and for example, the protection layer may include ruthenium (Ru).

Many materials highly absorb EUV light. Thus, a lithography method using EUV light uses a reflection mask instead of a general transmissive mask. The reflection mask 100 includes the absorption pattern 111. The absorption pattern 111 absorbs the EUV light L and is disposed on the reflection layer 112, which is highly reflective with respect to the EUV light L. Accordingly, a portion of the upper surface of the reflection layer 112 that is covered by the absorption pattern 111 corresponds to an absorption region, and a portion of the upper surface of the reflection layer 112 that is exposed by the absorption pattern 111 corresponds to a reflection region.

The EUV light L is reflected by the reflection region and reaches a wafer structure 300, thereby exposing a photoresist film 313 of the wafer structure 300 to form a photoresist pattern corresponding to the shape of the absorption pattern 111. This process is referred to as an EUV photolithography process. The wafer structure 300 includes a wafer substrate 311, a target layer 312 disposed on the wafer substrate 311, and the photoresist film 313 disposed on the target layer 312.

In a photolithography process using a photomask, the photomask is fixed. In a conventional photolithography process using a transmissive mask, the photolithography process is performed under atmosphere pressure, and thus, the transmissive mask may be fixed by a pressure difference between the transmissive mask and a fixing portion that causes formation of a local vacuum. However, in a EUV photolithography process, the photolithography process is performed in a vacuum condition, and a reflection mask for EUV lithography may not be fixed by a pressure difference causing formation of a local vacuum.

Accordingly, the reflection mask 100 may be fixed by an electrical attraction force generated by an electrostatic chuck (ESC) 200. Thus, a lowermost surface of the reflection mask 100 may include the conductive layer 114. The conductive layer 114 may include a chromium-containing material, for example, chromium nitride (CrN), but example embodiments are not limited thereto. The lowermost surface of the reflection mask 100 faces an uppermost surface of the reflection mask 100 through which the EUV light enters and by which the EUV light L is reflected. The conductive layer 114 may be disposed on a lower surface of the substrate 113. The conductive layer 114 may be disposed at a distance from an edge of the substrate 113. Thus, a Z-X cross-sectional area of the conductive layer 114 may be smaller than a Z-X cross-sectional area of the substrate 113. Accordingly, the lowermost surface of the reflection mask 100 may include a lower surface of the conductive layer 114.

The ESC 200 may include a clamp 214, an electrode 213 disposed in the clamp 214, and an array of plurality of pins 211 disposed on the clamp 214 and directly contacting the conductive layer 114. The plurality of pins 211 are disposed as an array form.

An alignment key 120 may be disposed on a lower (and/or lowermost surface) of the reflection mask 100, for example a lower surface of the conductive layer 114, but example embodiments are not limited thereto. The alignment key 120 is a pattern used for aligning the reflection mask 100 and the ESC 200. An alignment sensor 212 sensing the alignment key 120 may be disposed on the uppermost surface of the ESC 200.

Relative positions of the ESC 200 and the reflection mask 100 may be determined by the alignment key 120. Thus, when the reflection mask 100 is fixed on the ESC 200, a loading error may be reduced (and/or minimized).

Also, the reflection mask 100 and the ESC 200 may be moved in relative directions with reference to the alignment key 120 before the reflection mask 100 and the ESC 200 contact each other and/or are fixed by the alignment key 120. For example, a first drive unit 500 may be configured to move the ESC 200 in the X, Y, and/or Z direction. A second drive unit 520 may be configured to move the reflection mask 100 in the X, Y, and/or Z direction. Both the first drive unit 500 and the second drive unit 520 may be connected to a main controller 510. The main controller 510 may be configured to receive information indicating the respective positions of the reflection mask 100 and the ESC 200 with reference to the alignment key 120, for example based on the alignment sensor 212 sensing the alignment key 120 and based on at least one position sensor (not shown) sensing a position of the ESC 200 and the reflection mask 100. Based on the reflection mask 100 and/or ESC 200 position information received by the main controller 510, the main controller 510 may direct the first drive unit 500 to move the reflection mask 100 to a new position, and/or the main controller 510 may direct the second drive unit 520 to move the ESC 200 to a new position in order to align the ESC 200 and the reflection mask 100 with reference to the alignment key 120. While FIG. 1 illustrates a first drive unit 500, a main controller 510, and a second drive unit 520 facilitating the movement of the reflection mask 100 and/or the ESC 200 with reference to the alignment key 120, example embodiments are not limited thereto and other techniques for moving the reflection mask 100 and/or ESC 200 in relative directions with reference to the alignment key 120 may be used.

The alignment key 120 may be a concave or convex pattern on a lower surface (and/or the lowermost surface) of the reflection mask 100. The concave or convex pattern may include one of a trench pattern, a hole pattern, and a cavity pattern.

An inverse structure of the structure illustrated in FIG. 1 may also be used. In this case, the reflection mask 100 is fixed under the ESC 200, and the wafer structure 300 may be disposed under the reflection mask 100. Accordingly, terms such as ‘on’ and ‘uppermost surface’ used with reference to FIG. 1 may be replaced with terms ‘under’ and ‘lowermost surface.’

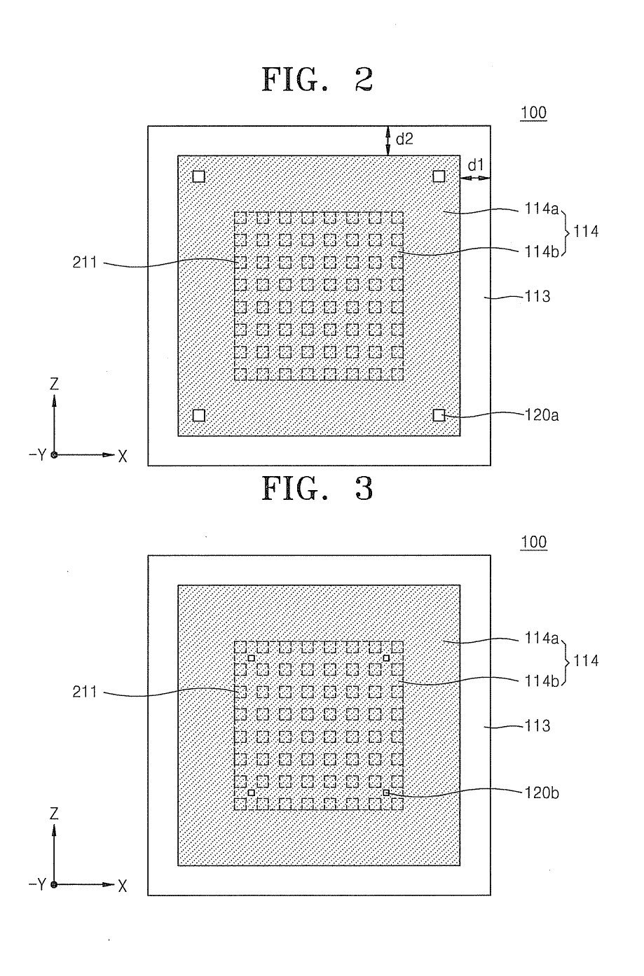

FIGS. 2 through 5 are plan views each illustrating a position where an alignment key is disposed according to example embodiments of the inventive concepts.

FIG. 2 is a plan view of the lowermost surface of the reflection mask 100a, according to example embodiments of the inventive concepts.

Referring to FIG. 2, the conductive layer 114 is disposed under the substrate 113. The conductive layer 114 has a first region 114b and a second region 114a. The first region 114b includes a region with which all of the pins 211 contact. The first region 114b may have square shape, but example embodiments are not limited thereto. The second region 114a surrounds the first region 114b. The boundary between the first region 114b and the second region 114a is illustrated as a dashed line. Although the array of pins 211 are not included in the reflection mask 100, the array of pins 211 are illustrated as relatively smaller dashed line squares in comparison to the dashed line square of the boundary, for ease of description. Also, in the drawings of the present application, the first region 114b of the conductive layer 114 is illustrated with a size other than its actual size, for ease of description.

In addition, the conductive layer 114 may be formed at a distance (d1, d2) from the edge of the substrate 113, and thus, an area (Z-X cross-sectional area) of the conductive layer 114 may be smaller than an area (Z-X cross-sectional area) of the substrate 113. While FIG. 2 illustrates the distances d1 and d2 are the same, example embodiments are not limited thereto and the distances d1 and d2 may be different. A lower surface of the reflection mask 100a may include the lower surface of the conductive layer 114 and/or the portion of the lower surface of the substrate 113 exposed by the conductive layer 114.

At least one alignment key 120a may be disposed on the lower surface of the conductive layer 114. For example, the alignment key 120a may be disposed in the second region 114a of the conductive layer 114. The alignment key 120a may be a concave or convex pattern on the lowermost surface of the reflection mask 100, for example, on the lower surface of the conductive layer 114.

FIG. 3 is a plan view of the lowermost surface of the reflection mask 100b, according to example embodiments of the inventive concepts.

In FIGS. 2 and 3, the same reference numerals denote the same elements, and thus, the same elements will not be described in detail herein.

Referring to FIG. 3, an alignment key 120b may be disposed on the lower surface of the conductive layer 114. For example, the alignment key 120b may be disposed in the first region 114b of the conductive layer 114. The alignment key 120b may be disposed in regions of the conductive layer 114 that directly contact the array of pins 211. The alignment key 120b may be disposed between the array of pins 211. The alignment key 120b disposed in the first region 114b of the conductive layer 114 may be smaller than the alignment key 120a disposed in the second region 114a of the conductive layer 114 illustrated in FIG. 2. The alignment key 120b may be a concave or convex pattern on the lower surface of the conductive layer 114 and/or alternatively on the lower surface of the substrate 113.

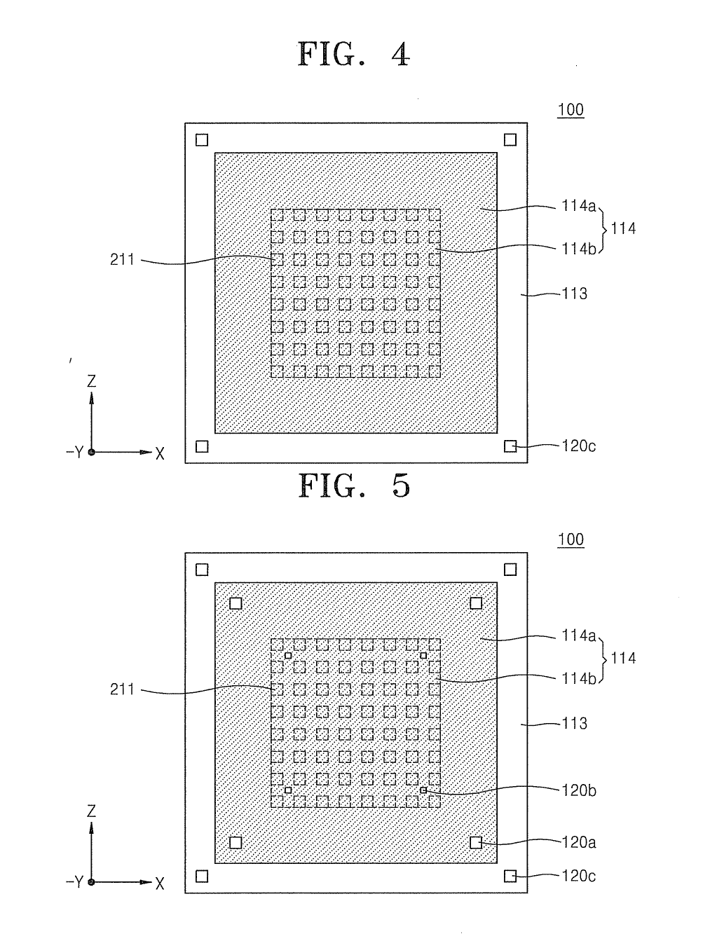

FIG. 4 is a plan view of the lowermost surface of the reflection mask 100c, according to example embodiments of the inventive concepts.

In FIGS. 2 and 3, the same reference numerals denote the same elements, and thus, the same elements will not be described in detail herein.

Referring to FIG. 4, an alignment key 120c may be on the portion of the lower surface of the substrate 113 exposed by the conductive layer 114. The alignment key 120c may be a concave or convex pattern on the portion of the lower surface of the substrate 113 exposed by the conductive layer 114.

FIG. 5 is a plan view of the lowermost surface of the reflection mask 100d, according to example embodiments of the inventive concepts.

In FIGS. 2 and 5, the same reference numerals denote the same elements, and thus, the same elements will not be described in detail herein.

The reflection mask 100 according to example embodiments may include at least one of the alignment keys 120a, 120b, 120c, and combinations thereof, as described with reference to FIGS. 2 through 4.

Referring to FIG. 5, the reflection mask 100d may include alignment keys 120a, 120b, and 120c described with reference to FIGS. 2 through 4. The alignment key 120a, 120b, and 120c may be respectively disposed on the lower surface of the conductive layer 114 in the second region 114a of the conductive layer 114, on the lower surface of the conductive layer 114 in the first region 114b of the conductive layer 114, and on the portion of the lower surface of the substrate 113 exposed by the conductive layer 114.

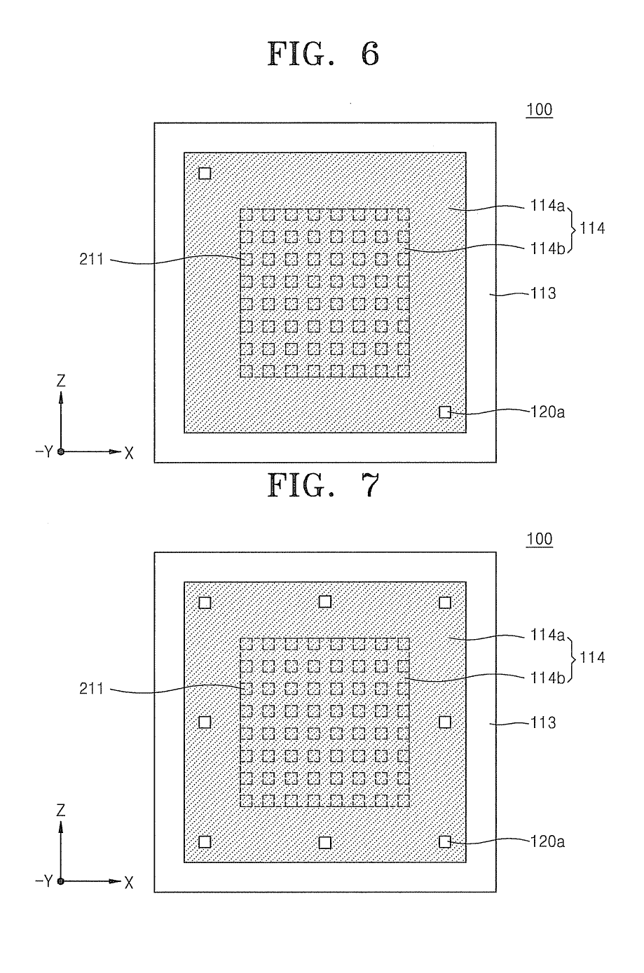

FIGS. 6 and 7 are plan views illustrating the number of alignment keys according to example embodiments of the inventive concepts.

FIG. 6 is a plan view for explaining the number of alignment keys according to example embodiments of the inventive concepts.

In FIGS. 2 and 6, the same reference numerals denote the same elements, and thus, the same elements will not be described in detail herein.

Referring to FIG. 6, the alignment key 120a may be positioned in at least two regions of the reflection mask 100e. This is because at least two reference regions are required to precisely determine relative positions of the reflection mask 100e and the ESC 200 and positions of various defects on the lowermost surface of the reflection mask 100e.

In FIG. 6, two alignment keys 120a are disposed in a diagonal direction of the second region 114a of the conductive layer 114. However, the positions of the alignment keys 120a are provided for description, and example embodiments of the inventive concepts are not limited thereto. For example, the mask 100e may include at least two of 120a, 120b, and 120c illustrated in FIG. 5.

FIG. 7 is a plan view for explaining the number of alignment keys according to example embodiments of the inventive concepts.

In FIGS. 2 and 7, the same reference numerals denote the same elements, and thus, the same elements will not be described in detail herein.

Referring to FIG. 7, unlike the alignment keys 120a illustrated in FIG. 2, the alignment keys 120a may also be disposed in various other regions, in addition to the diagonal corners. For example, alignment keys may be additionally disposed in a central region of each side of the conductive layer 114 in the second region 114a of the conductive layer 114, in addition to the four diagonal corners. Therefore, a total of eight alignment keys 120a are disposed in the second region 114a of the conductive layer 114.

More alignment keys may lead to a smaller time period to determine relative positions of the reflection mask 100 and the ESC 200 and positions of various defects on the lowermost surface of the reflection mask 100. Because reference points for determining the positions are disposed in various regions, scanning time may be reduced.

Alternatively, the alignment keys 120a may be additionally disposed in other regions of the lower surface of the conductive layer 114 and regions of the portion of the lower surface of the substrate 113 exposed by the conductive layer 114.

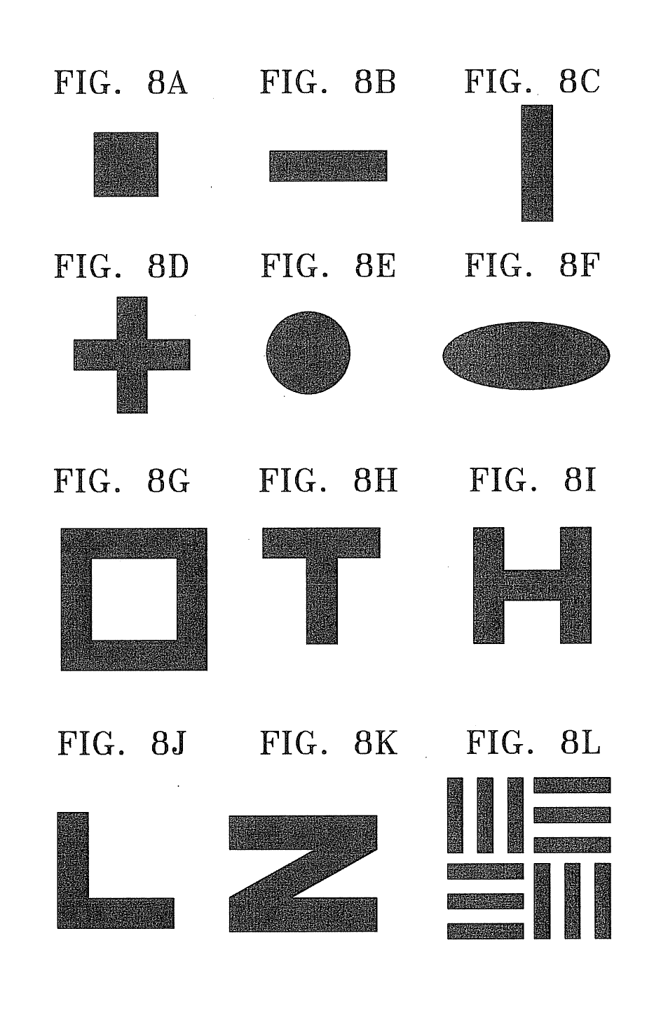

FIGS. 8A through 8L are plan views of alignment keys according to example embodiments of the inventive concepts.

In the reflection masks 100a, 100b, 100c, 100d, 100e, and 100f, illustrated in FIGS. 2 through 7, for ease of description, the alignment keys 120a, 120b, and 120c may have square shapes.

However, besides the square shapes (see FIG. 8A), the alignment keys 120a, 120b, and 120c may also have a polygonal shape, such as one of a triangular shape, a pentagonal shape, a hexagonal shape, and an octagonal shape. Also, the alignment keys 120a, 120b, and 120c may have a transversal line-shape (see FIG. 8B), a longitudinal line-shape (see FIG. 8C), a cross-shape (see FIG. 8D), a circular shape (see FIG. 8E), or an oval shape (see FIG. 8F). Furthermore, the alignment keys 120a, 120b, and 120c may have shape including at least one of linear shapes, the polygonal shapes, an oval shape, and a circular shape. Also, by variously connecting line-shaped alignment keys, the alignment keys 120a, 120b, and 120c may have a hollow square shape (see FIG. 8G), a T-shape (see FIG. 8H), an H-shape (see FIG. 81), an L-shape (see FIG. 8J), or a Z-shape (see FIG. 8K). Furthermore, by spacing linear alignment keys, the alignment keys 120a, 120b, and 120c may have a shape illustrated in FIG. 8L.

Hereinbefore, the alignment keys 120a, 120b, and 120c formed on the lowermost surface of the reflection mask 100 have a concave pattern. However, example embodiments of the inventive concepts are not limited thereto. For example, in example embodiments, the alignment keys 120a, 120b, and 120c formed on the lowermost surface of the reflection mask 100 may instead have a convex pattern.

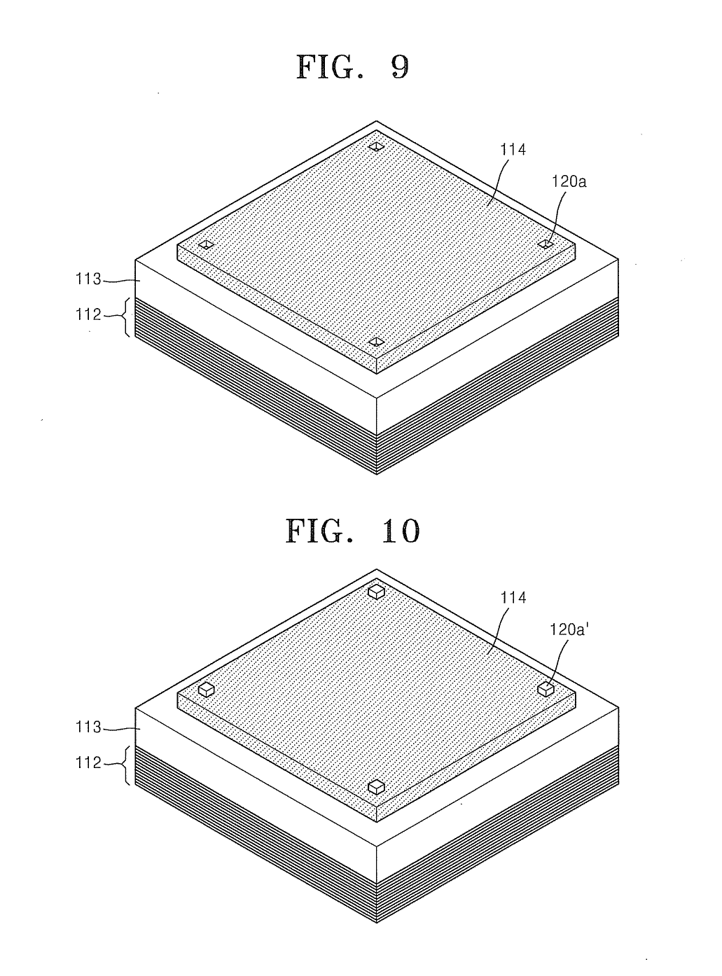

FIG. 9 is a perspective view of an alignment key according to example embodiments of the inventive concepts, in which the alignment key has a concave pattern, and FIG. 10 is a perspective view of an alignment key according to example embodiments of the inventive concepts, in which the alignment key has a convex pattern (and/or a pattern that protrudes outward).

In FIGS. 2, 9, and 10, the same reference numerals denote the same elements, and thus, the same elements will not be described in detail herein.

Referring to FIG. 9, the alignment key 120a disposed on the lower surface of the conductive layer 114 has a concave pattern. Referring to FIG. 10, the alignment key 120a′ disposed on the lower surface of the conductive layer 114 has a convex pattern.

Although not illustrated herein, example embodiments of the inventive concepts, the concave pattern and the convex pattern may be both disposed according to where an alignment key is positioned. For example, alignment keys disposed on the lower surface of the conductive layer 114 in the second region 114a of the conductive layer 114 may have concave patterns. Alignment keys disposed on the portion of the lower surface of the substrate 113 exposed by the conductive layer 114 may have convex patterns. According to example embodiments of the inventive concepts, alignment keys disposed on the lower surface of the conductive layer 114 in the first region 114b of the conductive layer 114 may have concave patterns and alignment keys disposed on the lower surface of the conductive layer 114 in the second region 114a of the conductive layer 114 may have convex patterns.

Furthermore, the concave and convex patterns may have uniform cross-sectional areas (and/or substantially uniform cross-sectional areas). However, the concave and convex patterns may instead have a cross-sectional area that changes continuously or discontinuously according to depth or height of the pattern. For example, each of the concave and convex patterns may have a step shape.

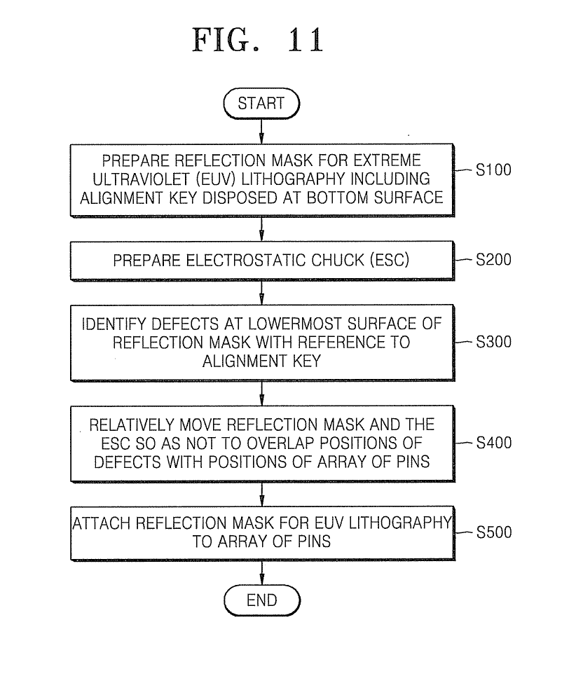

FIG. 11 is a flowchart for explaining a method of fixing a reflection mask for EUV lithography on an ESC, according to example embodiments of the inventive concepts.

Referring to FIG. 11, the method of fixing the reflection mask for EUV lithography on the ESC includes preparing a reflection mask including an alignment key disposed on a lower (and/or lowermost) surface facing a upper surface by which EUV light is reflected (operation S100), preparing an ESC including an array of a plurality of pins form that may contact the lowermost surface of the reflection mask, and an alignment sensor for sensing the alignment key (operation S200), identifying defects on the lowermost surface of the reflection mask with reference to the alignment key (operation S300), relatively moving the reflection mask and the ESC so as not to overlap the positions of defects identified with reference to the alignment key and the positions of the array of pins (operation S400), and attaching the reflection mask to the array of pins (operation S500.) The main controller 510, as illustrated in FIGS. 1, 12B, and 13B, may direct the first drive unit 500 to move the ESC 200 and/or the second drive unit 520 to move the reflection mask in the X, Y, and/or Z directions so as to not overlap the positions of defects identified with reference to the alignment key and the positions of the array of pins.

Operation S100 and operation S200 will not be described in detail herein because a description thereof has been presented above with reference to FIGS. 1 through 10.

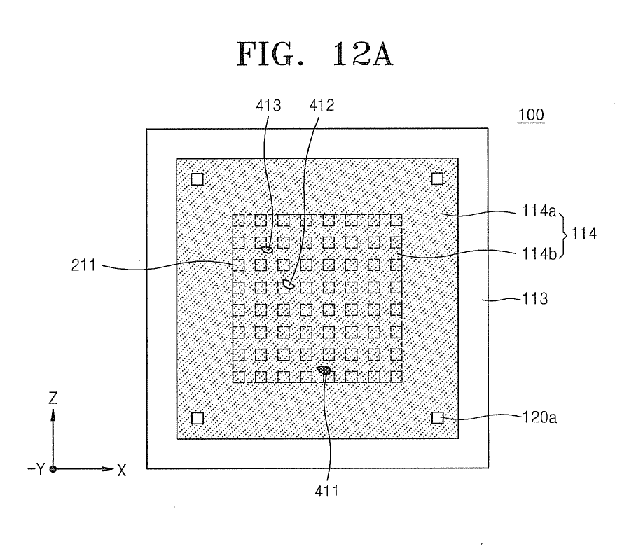

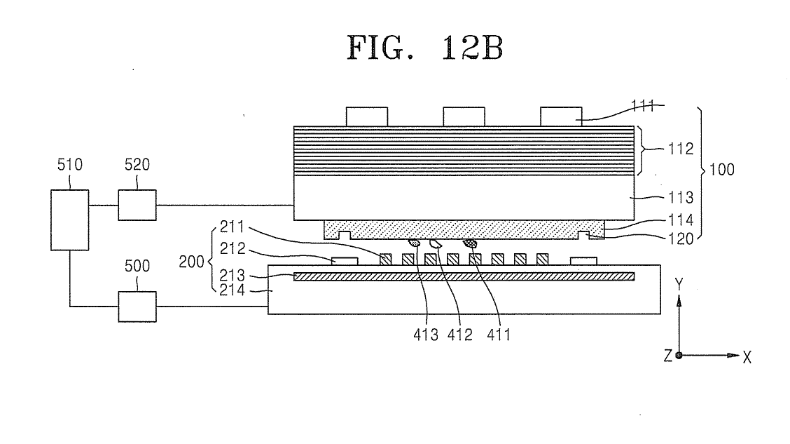

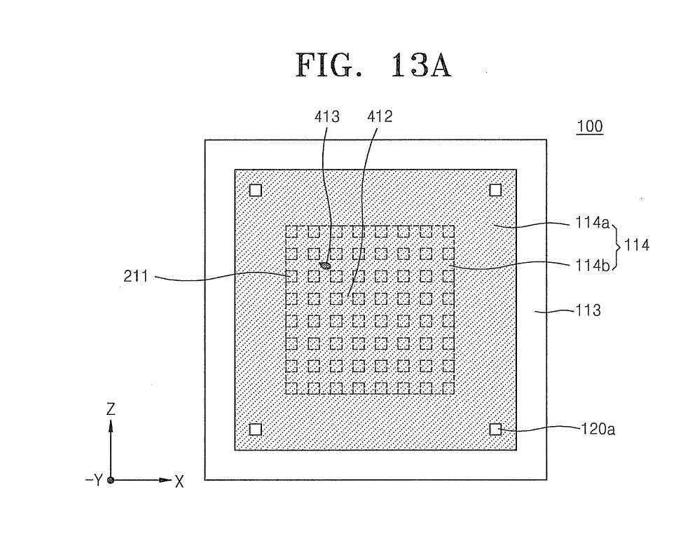

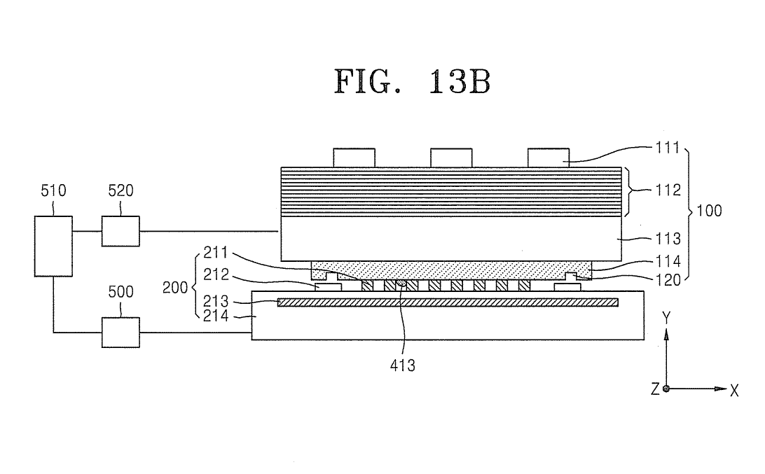

Operation S300 through S500 is described as follows with reference to FIGS. 12A, 12B, 13A, and 13B.

FIGS. 12A and 12B are, respectively, plan and sectional views for explaining operation S300 in which defects on the lowermost surface of the reflection mask 100 are identified with reference to an alignment key, according to example embodiments of the inventive concepts.

In FIGS. 1, 2, 12A and 12B, the same reference numerals denote the same elements, and thus, the same elements will not be described in detail herein.

Referring to FIGS. 12A and 12B, the reflection mask 100 is not yet attached to the ESC 200. Various defects 411, 412, and 413 may be at positions on the lowermost surface of the reflection mask 100. When the reflection mask 100 is attached to the ESC 200 without performing any process for removing the defects 411, 412, and 413, the defects 411, 412, and 413 and the array of pins 211 of the ESC 200 may overlap and thus, various related problems may occur. For example, the array of pins 211 is spaced apart from the reflection mask 100, and thus, the reflection mask 100 may not be securely fixed on the ESC 200. In addition, when the defects 411, 412, and 413 are formed of hard materials, if the reflection mask 100 is securely fixed on the ESC 200, the reflection mask 100 and/or the array of pins 211 may be deformed, and thus, an appropriate photolithography process may not be performed.

Accordingly, before the reflection mask 100 is attached to the ESC 200 and the reflection mask 100 and the ESC 200 are securely fixed to each other, the following operations may be required. First, the defects 411, 412, and 413 at positions on the lowermost surface of the reflection mask 100 are identified, the types of the defects 411, 412, and 413 are determined, and if removal of the determined defects is possible, the determined defects are removed; otherwise, the reflection mask 100 and the ESC 200 are aligned such that the positions of the determined defects and the positions of the array of pins 211 do not overlap.

In operation S300 for identifying the defects 411, 412, and 413 on the lowermost surface of the reflection mask 100, position, size, height, or shape of the defects 411, 412, and 413 is determined and the defects 411, 412, and 413 are classified according to type.

The process for identifying the defects 411, 412, and 413 on the lowermost surface of the reflection mask 100 may be performed by repeatedly performing a unit process comprising irradiating light to the lowermost surface of the reflection mask 100 and detecting the reflected light.

Also, the process for determining the position, size, height, or shape of the defects 411, 412, and 413 may be performed using coordinates of the defects 411, 412, and 413 obtained with reference to an alignment key, by using a scanning electron microscope (SEM), or an atomic force microscope (AFM).

Also, the process for determining the types of the defects 411, 412, and 413 may include a process for classifying defects to be removed or repaired from defects to be removed or repaired. For example, the defects 411, 412, and 413 may be classified as defects to be removed by washing, defects to be removed by laser-repairing, and defects not to be removed by washing, laser-repairing, or both. An example of the defect to be removed by washing is the first defect 411, an example of the defect to be removed by laser-repairing is the second defect 412, and an example of the defect not to be removed by any one of washing and laser-repairing is the third defect 413.

Regarding the first defect 411 to be removed by washing, operation S300 may be followed by an operation in which the lowermost surface of the reflection mask 100 is washed. Also, regarding the second defect 412 to be removed by laser-repairing, operation S300 may be followed by an operation in which the second defect 412 is removed by laser-repairing.

The process for determining the position, size, height, or shape of the defects 411, 412, and 413 and the process for determining the types of the defects 411, 412, and 413 require formation of the alignment key 120 as a reference on the lowermost surface of the reflection mask 100. Also, the operation for removing the second defect 412 by laser-repairing requires the formation of the alignment key 120 as a reference on the lowermost surface of the reflection mask 100.

FIGS. 13A and 13B are, respectively, plan and cross-sectional views illustrating operation S400 in which the reflection mask 100 and the ESC 200 are relatively moved with reference to an alignment key and operation S500 in which the reflection mask 100 is attached to the array of pins, according to example embodiments of the inventive concepts.

In FIGS. 1, 2, 13A and 13B, the same reference numerals denote the same elements, and thus, the same elements will not be described in detail herein.

Referring to FIGS. 13A and 13B, after the defects 411 and 412 that can be removed by washing and/or laser-repairing are removed, the reflection mask 100 and the ESC 200 may be relatively moved with reference to the alignment key 120 so as not to overlap the positions of the third defect 413 not to be removed by the washing and the laser-repairing and the positions of the array of pins 211 (S400). Thus, the third defect 413 is positioned between the pins 211, and thus, problems that may occur during the reflection mask 100 is attached to the ESC 200 and the reflection mask 100 is fixed on the ESC 200 when the defects are not removed may be prevented. The relative movement requires formation of the alignment key 120 as a reference on the lowermost surface of the reflection mask 100.

Subsequently, the reflection mask 100 is attached to the array of pins 211 and the reflection mask 100 is fixed on the ESC 200 due to an electrical attraction force (operation S500.)

While the inventive concept has been particularly shown and described with reference to exemplary embodiments thereof, it will be understood that various changes in form and details may be made therein without departing from the spirit and scope of the following claims.

What is claimed, is:

1. A reflection mask comprising:
an upper surface configured to reflect extreme ultraviolet EUV light;
a lower surface opposite the upper surface,
the lower surface including at least one alignment key.

2. The reflection mask of claim 1, further comprising:
a conductive layer;
a substrate on the conductive layer;
a reflection layer on the substrate,
the reflection layer defining the upper surface configured to reflect extreme ultraviolet EUV light, and
an absorption pattern on the reflection layer,
the absorption pattern exposing the upper surface of the reflection layer.

3. The reflection mask of claim 2, wherein
an edge of the substrate extends a distance wider than an edge of the conductive layer.

4. The reflection mask of claim 2, wherein
an area size of the conductive layer is smaller than an area size of the substrate.

5. The reflection mask of claim 2, wherein
the conductive layer includes the at least one alignment key.

6. The reflection mask of claim 2, wherein
the conductive layer exposes a portion of the substrate, and
the exposed portion of the substrate includes the at least one alignment key.

7. The reflection mask of claim 1, further comprising:
a conductive layer including a lowermost surface of the reflection mask,
the conductive layer being configured to attach to an electrostatic chuck (ESC) in order to fix the reflection mask to the ESC, and
the ESC including a sensor that is configured to sense the at least one alignment key in order for at least one drive unit to align the reflection mask and the ESC.

8. The reflection mask of claim 1, wherein
the at least one alignment key includes a convex pattern that protrudes from the reflection mask.

9. The reflection mask of claim 1, wherein
the at least one alignment key includes a concave pattern in defined by the lower surface of the reflection mask.

10. The reflection mask of claim 1, wherein
the at least one alignment key includes at least one of a line-shape, a polygonal shape, an oval shape, and a circular shape.

11. The reflection mask of claim 1, wherein
a first region of the lower surface of the reflection mask includes at least one of the at least one alignment key, and
a second region of the lower surface of the reflection mask includes at least one of the at least one alignment key.

12. The reflection mask of claim 1, further comprising:
an absorption pattern that exposes the upper surface configured to reflect extreme ultraviolet EUV light.

13. The reflection mask of claim 1, further comprising:
a protection layer between the upper surface and the lower surface.

14. The reflection mask of claim 1, wherein
the conductive layer includes a lowermost surface,
the lowermost surface of the conductive layer is the lower surface including the at least one alignment key,
the lowermost surface includes a first region and a second region,
the first region of the conductive layer includes a plurality of first alignment keys,
the second region of the conductive layer surrounds the first region of the conductive layer,
the second region of the conductive layer includes a plurality of second alignment keys,
and a size of the first alignment keys in the first region is smaller than a size of the at second alignment keys in the second region.

15. A system comprising the reflection mask of claim 1, and further including:
an array of a plurality of pins configured to contact a lowermost surface of the reflection mask; and
an electrostatic chuck (ESC) including an alignment sensor,
the alignment sensor configured to sense at least one alignment key on a lower surface of a reflection mask.

16. The system of claim 15, further comprising:
at least one drive unit configured to move one of the reflection mask and the ESC relative to each other, based on reference to the at least one alignment key.

17. The system of claim 15, wherein the reflection mask comprises:
a conductive layer;
a substrate on the conductive layer;
a reflection layer on the substrate,
the reflection layer defining the upper surface of the reflection mask configured to reflect extreme ultraviolet EUV light; and
an absorption pattern on the reflection layer,
the absorption pattern exposing the upper surface of the reflection layer.

18. The system of claim 15, wherein
the conductive layer defines a lowermost surface that is the lower surface including at least one alignment key,
the conductive layer includes a first region and a second region,
the first region of the conductive layer includes at least one of the at least one alignment key,
the first region is configured to contact the array of pins of the ESC,
the second region of the conductive layer surrounds the first region of the conductive layer,
the second region of the conductive layer includes at least one of the at least one alignment key, and
a size of the at least one the alignment key in the first region is smaller than a size of the at least one alignment key in the second region.

19. A reflection mask comprising:
a reflection layer including an upper surface,
the reflection layer including a plurality of alternating silicon films and non-silicon films,
the non-silicon films including one of molybdenum (Mo) and beryllium (Be); and
the reflection mask including a lower surface including at least one alignment key.

20. A system comprising:
an electrostatic chuck (ESC) including an alignment sensor and a plurality of pins,
the alignment sensor configured to sense at least one alignment key on a lower surface of a reflection mask,
the reflection mask including an upper surface configured to reflect extreme ultraviolet EUV light, and
the plurality of pins configured to contact a lowermost surface of the reflection mask.
